(19) United States
(12) Patent Application Publication
(10) Pub. No.: US 2024/0304684 A1
(43) Pub. Date: Sep. 12, 2024

(54) Thin Film Transistor and Preparation Method thereof, Display Substrate and Display Apparatus

(71) Applicants: Hefei Xinsheng Optoelectronics Technology Co., Ltd., Hefei, Anhui (CN); BOE Technology Group Co., Ltd., Beijing (CN)

(72) Inventors: Ming WANG, Beijing (CN); Liusong NI, Beijing (CN); Kangkang WU, Beijing (CN); Yingbin HU, Beijing (CN); Chen XU, Beijing (CN)

(21) Appl. No.: 18/028,221

(22) PCT Filed: Mar. 28, 2022
(86) PCT No.: PCT/CN2022/083438

§ 371 Date: Mar. 24, 2023

(51) Int. Cl. H01L 29/417; H01L 29/66; H01L 29/786

(52) U.S. Cl. CPC H01L 29/41733; H01L 29/66969; H01L 29/7869

(57) ABSTRACT

Disclosed are a thin film transistor and preparation method thereof, display substrate and display apparatus. The thin film transistor includes a base substrate, a shielding layer, buffer layer, active layer, gate insulating layer and conductive layer stacked on the base substrate; the conductive layer includes a gate electrode, source electrode and drain electrode; the active layer includes a channel region, source transition region and drain transition region at two sides of the channel region, source connection region and drain connection region; the source transition region and drain transition region each include a first sub-region, second sub-region and third sub-region connected sequentially, first sub-region is located on a side of second sub-region away from the channel region, third sub-region is located on a side of second sub-region close to the channel region, a thickness of second sub-region is k times that of the channel region, k is 0.8 to 1.5.

### CROSS-REFERENCE TO RELATED APPLICATION

The present application is a U.S. National Phase Entry of International Application No. PCT/CN2022/083438 having an international filing date of Mar. 28, 2022, the content of which is incorporated into this application by reference.

### TECHNICAL FIELD

Embodiments of the present disclosure relate to, but are not limited to, the field of display technology, and particularly to a thin film transistor and a preparation method thereof, a display substrate and a display apparatus.

### BACKGROUND

An Organic Light Emitting Diode (OLED) and a Quantum dot Light Emitting Diode (QLED) are active light emitting display apparatuses, and have advantages of self-illumination, a wide angle of view, a high contrast ratio, low power consumption, an extremely high response speed, lightness and thinness, bendability, and a low cost, etc. With continuous development of display technologies, a display apparatus using the OLED or the QLED as a light emitting device and using a Thin Film Transistor (TFT) for signal control has become a mainstream product in the field of display at present. The TFT is the main switching element in the display apparatus at present, and the electrical characteristics of the TFT are directly related to the display effect of the display apparatus.

### SUMMARY

The following is a summary of subject matters described herein in detail. The summary is not intended to limit the protection scope of claims.

In a first aspect, an embodiment of the present disclosure provides a thin film transistor, including a base substrate, and a shielding layer, a buffer layer, an active layer, a gate insulating layer and a conductive layer that are stacked on the base substrate.

The conductive layer includes a gate electrode, a source electrode and a drain electrode.

The active layer includes a channel region, a source transition region and a drain transition region that are located at two sides of the channel region, a source connection region located on a side of the source transition region away from the channel region, and a drain connection region located on a side of the drain transition region away from the channel region.

The source connection region is connected with the source electrode, and the drain connection region is connected with the drain electrode.

The source transition region and the drain transition region each include: a first sub-region, a second sub-region and a third sub-region sequentially connected, the first sub-region is located on a side of the second sub-region away from the channel region, the third sub-region is located on a side of the second sub-region close to the channel region, the thickness of the second sub-region is k times the thickness of the channel region, k is 0.8 to 1.5.

In a second aspect, an embodiment of the present disclosure also provides a display substrate, which includes the thin film transistor described in the above embodiment.

In a third aspect, an embodiment of the disclosure further provides a display apparatus, including the display substrate as described in the abovementioned embodiment.

In a fourth aspect, an embodiment of the present disclosure provides a preparation method of a thin film transistor, including:
forming a shielding layer, a buffer layer and an active layer sequentially on a base substrate;
forming a gate insulating layer and a conductive layer sequentially on the active layer, by performing two conductorization treatments, forming, in the active layer, a channel region, a source transition region and a drain transition region that are located at two sides of the channel region, a source connection region located on a side of the source transition region away from the channel region, and a drain connection region located on a side of the drain transition region away from the channel region; the conductive layer includes a gate electrode, a source electrode and a drain electrode; the source connection region is connected with the source electrode, and the drain connection region is connected with the drain electrode; the source transition region and the drain transition region each include: a first sub-region, a second sub-region and a third sub-region connected sequentially, the first sub-region is located on a side of the second sub-region away from the channel region, the third sub-region is located on a side of the second sub-region close to the channel region, a thickness of the first sub-region and a thickness of the third sub-region are both equal to a thickness of the channel region, a thickness of the second sub-region is k times the thickness of the channel region, k is 0.8 to 1.5.

Other characteristics and advantages of the present disclosure will be set forth in the following specification, and moreover, partially become apparent from the specification, or are understood by implementing the present disclosure. Other advantages of the present disclosure may be achieved and obtained through solutions described in the specification and drawings.

Other aspects may be understood upon reading and understanding the drawings and the detailed description.

### BRIEF DESCRIPTION OF DRAWINGS

The drawings are used for providing understanding of technical solutions of the present disclosure, constitute a part of the specification, and together with the embodiments of the present disclosure, are used for explaining the technical solutions of the present disclosure, but do not form limitations on the technical solutions of the present disclosure. Shapes and sizes of various components in the drawings do not reflect actual scales, and are only intended to schematically illustrate contents of the present disclosure.

FIG. 1A is a schematic diagram after a first conductorization treatment in some techniques.

FIG. 1B is a schematic diagram after formation of a pattern of a conductive layer in some technologies.

FIG. 1C is a schematic diagram after a second conductorization treatment in some techniques.

FIG. 2 is a schematic diagram of a structure of a thin film transistor according to an exemplary embodiment of the present disclosure.

FIG. 3 is a schematic diagram of another structure of a thin film transistor according to an exemplary embodiment of the present disclosure.

FIG. 4 is a schematic diagram of yet another structure of a thin film transistor according to an exemplary embodiment of the present disclosure.

FIG. 5 is a schematic diagram after a pattern of a shielding layer is formed according to an exemplary embodiment of the present disclosure.

FIG. 6 is a schematic diagram of deposition of a second metal oxide film according to an exemplary embodiment of the present disclosure.

FIG. 7 is a schematic diagram after a first etching process is performed on a first metal oxide film and a second metal oxide film according to an exemplary embodiment of the present disclosure.

FIG. 8 is a schematic diagram after formation of an active layer pattern according to an exemplary embodiment of the present disclosure.

FIG. 9 is a schematic diagram after formation of a pattern of a gate insulating layer and a first conductorization treatment according to an exemplary embodiment of the present disclosure.

FIG. 10 is a schematic diagram after formation of a pattern of a conductive layer according to an exemplary embodiment of the present disclosure.

FIG. 11 is a schematic diagram after a second etching is performed on a gate insulating layer according to an exemplary embodiment of the present disclosure.

FIG. 12 is a schematic diagram after a second conductorization treatment and formation of a pattern of a passivation layer according to an exemplary embodiment of the present disclosure.

FIG. 13 is a schematic diagram after a second conductorization treatment according to an exemplary embodiment of the present disclosure.

### DETAILED DESCRIPTION

Multiple embodiments are described herein, but the description is exemplary rather than restrictive, and there may be more embodiments and implementation solutions within the scope contained in the embodiments described herein. Although many possible feature combinations are shown in the drawings and discussed in exemplary implementations, many other combinations of the disclosed features are possible. Unless expressly limited, any feature or element of any embodiment may be used in combination with, or may replace, any other feature or element in any other embodiment.

When a representative embodiment is described, a method or process may have already been presented in a specific sequence of acts in the specification. However, to an extent that the method or process does not depend on a specific sequence of the acts herein, the method or process should not be limited to the acts in the specific sequence. As will be understood by those of ordinary skill in the art, other act orders are possible. Therefore, the specific order of the acts illustrated in the specification should not be interpreted as a limitation on claims. In addition, the claims with respect to the method or process should not be limited to execute their acts according to the written order. Those skilled in the art may easily understand that these orders may change, and are still maintained in the spirit and scope of the embodiments of the disclosure.

Scales of the drawings in the present disclosure may be used as a reference in the actual process, but are not limited thereto. For example, the width-length ratio of the channel, thicknesses and spacings of various film layers, etc., can be adjusted according to actual needs. For example, in the drawings, a dimension of each constituent element, a thickness of a layer, or a region is exaggerated sometimes for clarity. Therefore, an implementation of the present disclosure is not necessarily limited to the size shown, and a shape and size of each component in the drawings do not reflect true proportions. In addition, the drawings schematically illustrate ideal examples, and one implementation of the present disclosure is not limited to the shapes, numerical values, or the like shown in the drawings.

The “first”, “second”, “third” and other ordinal numbers in the exemplary embodiments of the present disclosure are used to avoid confusion of constituent elements, not to provide a limitation in quantity.

In the exemplary embodiments of the present disclosure, for the sake of convenience, wordings such as “central”, “upper”, “lower”, “front”, “rear”, “vertical”, “horizontal”, “top”, “bottom”, “inner”, “outer” and the others describing the orientations or positional relations are used to depict the relationship of constituent elements with reference to the drawings, which are only for an easy and simplified description of the present disclosure, rather than for indicating or implying that the device or element referred to must have a specific orientation, or must be constructed and operated in a particular orientation and therefore, those wordings cannot be construed as limitations on the present disclosure. The positional relationships between the constituent elements may be changed as appropriate according to a direction which is used for describing each constituent element. Therefore, appropriate replacements may be made according to situations without being limited to the wordings described in the specification.

In the exemplary embodiments of the present disclosure, the terms “install”, “connect” and “couple” shall be broadly understood unless otherwise explicitly specified and defined. For example, a connection may be a fixed connection, or a detachable connection, or an integrated connection. It may be a mechanical connection or an electrical connection. It may be a direct mutual connection, or an indirect connection through middleware, or internal communication between two components. Those of ordinary skills in the art may understand meanings of the above-mentioned terms in the present disclosure according to situations.

In the exemplary embodiments of the present disclosure, “an electrical connection” includes a case where constituent elements are connected via an element having a certain electrical effect. The “element with the certain electrical effect” is not particularly limited as long as electrical signals may be sent and received between the connected constituent elements. For example, “the element with the certain electrical effect” may be an electrode or wiring, or a switch element, such as a transistor, or other functional elements, such as a resistor, an inductor, a capacitor, or the like.

In an exemplary embodiment of the present disclosure, a transistor refers to an element that at least includes three terminals, i.e., a gate electrode (gate or control electrode), a drain electrode (drain electrode terminal, drain region, or drain), and a source electrode (source electrode terminal, source region, or source). A transistor has a channel region between a drain electrode and a source electrode, and a current can flow through the drain electrode, the channel region, and the source electrode. It is to be noted that, in the specification, the channel region refers to a region through which the current mainly flows.

In an exemplary embodiment of the present disclosure, in order to distinguish two electrodes of a transistor other than a gate electrode (gate electrode or control electrode), one of the two electrodes is directly described as a first electrode, while the other is described as a second electrode. The first electrode may be a drain electrode, and the second electrode may be a source electrode. Or, the first electrode may be a source electrode, and the second electrode may be a drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the specification.

In the exemplary embodiments of the present disclosure, “parallel” refers to a state in which two straight lines form an angle −10 degrees or more and 10 degrees or less, and thus also includes a state in which the angle is −5 degrees or more and 5 degrees or less. In addition, “perpendicular” refers to a state in which an angle formed by two straight lines is 800 or more and 100° or less, and thus also includes a state in which the angle is 850 or more and 950 or less.

In the specification, a “film” and a “layer” are interchangeable. For example, a “conductive layer” may be replaced with a “conductive film” sometimes. Similarly, an “insulating film” may be replaced with an “insulating layer” sometimes.

Triangle, rectangle, trapezoid, pentagon and hexagon in this specification are not strictly defined, and they may be approximate triangle, rectangle, trapezoid, pentagon or hexagon, etc. There may be some small deformation caused by tolerance, and there may be chamfer, arc edge and deformation, etc.

In the exemplary embodiments of the present disclosure, “about” means that there is not strict limit for a value, and values within an error range of processes and measurement are allowed.

With the rapid development of display technology, thin film transistor technology has developed from amorphous silicon (a-Si) thin film transistor to oxide (Oxide) thin film transistor. An active layer of the oxide thin film transistor adopts an oxide active layer, the carrier mobility of the oxide active layer is 20 to 30 times that of amorphous silicon active layer, and it has the characteristics of large mobility, a high on-state current, better switch characteristics and better uniformity, which can greatly improve the characteristics of thin film transistors, improve the response speed of pixels and achieve a faster refresh rate, and can be applied to applications requiring fast response and large current.

There are two types of oxide thin film transistors, that is, a bottom-gate type thin film transistor and a top-gate type thin film transistor. A structure of the bottom-gate type thin film transistors is characterized in that a source electrode and a drain electrode respectively cover two sides of an oxide active layer, and a channel region is formed between the source electrode and the drain electrode. A structure of the top-gate type thin film transistor is characterized in that a source electrode and a drain electrode are respectively connected with a mental oxide active layer through a via. Since the top-gate type thin film transistor has a characteristic of a short channel, the on-state current (Ion) is effectively improved, thus significantly improving the display effect, and effectively reducing the power consumption. Due to a small overlapping area between the gate electrode and the source and drain electrodes in the top-gate type thin film transistor, there are small parasitic capacitance generated, small circuit delay and high switch speed, the possibility of a defect, such as a gate-drain short circuit (GDS), or the like, is low.

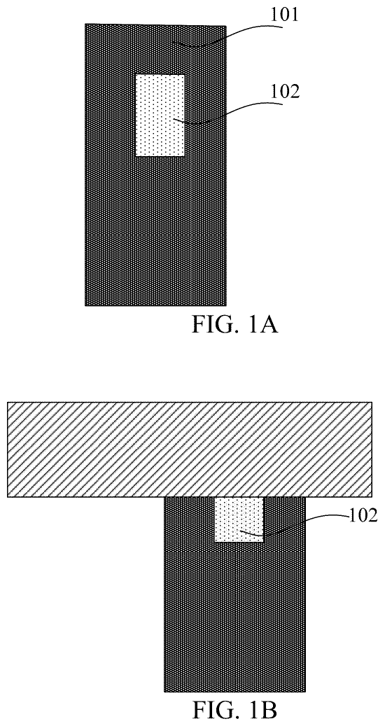

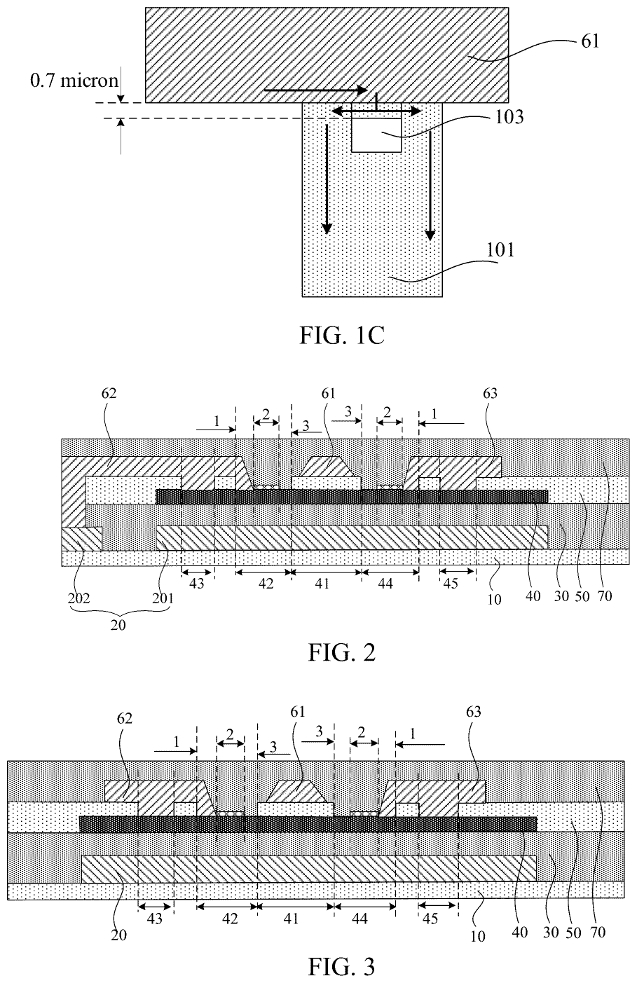

FIG. 1A is a schematic diagram after a first conductorization treatment in some techniques, FIG. 1B is a schematic diagram after formation of a pattern of a conductive layer in some techniques, and FIG. 1C is a schematic diagram after a second conductorization treatment in some techniques. In FIGS. 1A to 1C, the oxide active layer adopting IGZO is taken as an example. In FIGS. 1A and 113, a first region 101 in the oxide active layer is an unconductorized IGZO, and a second region 102 in the oxide active layer is a conductorized IGZO (formed by a first conductorization treatment); in FIG. 1C, the first region 101 in the oxide active layer is a conductorized IGZO (formed by a second conductorization treatment), a blank region 103 in the oxide active layer is a damaged IGZO, a first sub-region in the oxide active layer is a conductorized IGZO (formed by two conductorization treatments), and a second sub-region in the oxide active layer is a conductorized IGZO (formed by the first conductorization treatment). In addition, in FIG. 1C, an arrow indicating a current flow direction is taken as an example.

As shown in FIGS. 1A to 1C, in some display products prepared by Mask process, a gate insulating layer (GI) and a buffer layer are usually etched by one Mask in the process of preparing TFT, so the overall etching time of GI is longer, and an oxide active layer (such as IGZO) will be subjected to two dry etching processes and two conductorization treatments in a lapping region between the gate electrode (Gate) 61 and the oxide active layer. Therefore, as shown in FIG. 1C, it is easy to cause partial missing of the metal oxide active layer.

In addition, as shown in FIG. 1C, during the etching for the whole surface of GI, due to photoresist (PR) protection, only about 0.7 microns of conductorized IGZO can be retained in the edge region of the gate electrode, and the current mainly flows out through this IGZO. Therefore, due to the partial missing of the oxide active layer, the conduction channel is very short, which obviously limits the current flow capability, and the current output efficiency of the thin film transistor is decreased and the electrical characteristics of the thin film transistor is deteriorated. Furthermore, when the thin film transistor is applied to a display product, the display quality will be affected.

An embodiment of the present disclosure provides a thin film transistor. The thin film transistor may include a base substrate, and a shielding layer, a buffer layer, an active layer, a gate insulating layer and a conductive layer stacked on the base substrate.

The conductive layer may include a gate electrode, a source electrode, and a drain electrode.

The active layer may include a channel region, a source transition region and a drain transition region located at two sides of the channel region, a source connection region located on a side of the source transition region away from the channel region, and a drain connection region located on a side of the drain transition region away from the channel region.

The source connection region is connected with the source electrode, and the drain connection region is connected with the drain electrode.

Both the source transition region and the drain transition region may include a first sub-region, a second sub-region and a third sub-region connected sequentially, wherein the first sub-region is located on a side of the second sub-region away from the channel region, and the third sub-region is located on a side of the second sub-region close to the channel region, a thickness of the second sub-region may be k times a thickness of the channel region, and k may be 0.8 to 1.5.

For example, k may include, but is not limited to, 0.8, 0.85, 0.9, 0.95, 1, 1.5, 1.2, 1.25, 1.3, 1.35, 1.4, 1.45, 1.5, etc. Here, the embodiments of the present disclosure are not limited to this.

Herein, a thickness of a film layer may refer to a dimensional characteristic of the film layer in a direction perpendicular to a plane of a thin film transistor. For example, a thickness of a channel region of an active layer may refer to a dimensional characteristic of the channel region of the active layer in a direction perpendicular to the plane of the thin film transistor, a thickness of a second sub-region in a source transition region of the active layer may refer to a dimensional characteristic of the second sub-region in the source transition region of the active layer in a direction perpendicular to the plane of the thin film transistor, a thickness of a second sub-region in a drain transition region of the active layer may refer to a dimensional characteristic of the second sub-region in the drain transition region of the active layer in a direction perpendicular to the plane of the thin film transistor.

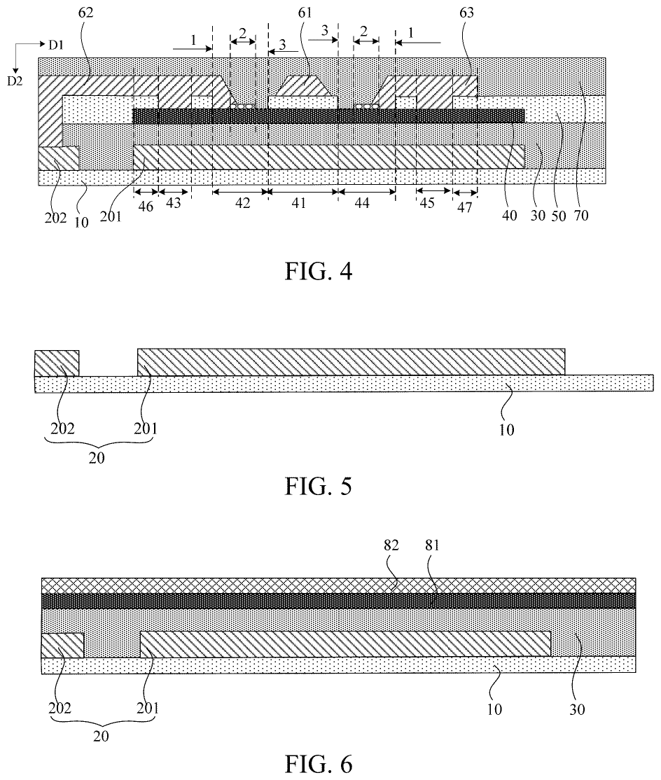

FIG. 2 is a schematic diagram of a structure of a thin film transistor in an exemplary embodiment of the present disclosure, FIG. 3 is a schematic diagram of another structure of a thin film transistor in an exemplary embodiment of the present disclosure, and FIG. 4 is a schematic diagram of yet another structure of a thin film transistor in an exemplary embodiment of the present disclosure. FIG. 2 to FIG. 4 are illustrated by taking a case where the thickness of the second sub-region is larger than the thickness of the channel region as an example.

In an exemplary embodiment, as shown in FIGS. 2 to 4, a thin film transistor according to an exemplary embodiment of the present disclosure may include: a base substrate 10, a shielding (SHL) layer 20 disposed on the base substrate 10, a buffer layer 30 disposed on a side of the shielding layer 20 away from the base substrate 10, an active (ACT) layer 40 disposed on a side of the buffer layer 30 away from the base substrate 10, a gate insulating (GI) layer 50 disposed on a side of the active layer 40 away from the base substrate 10, a conductive layer disposed on a side of the gate insulating layer 50 away from the base substrate 10, and a passivation layer 70 disposed on a side of the conductive layer away from the base substrate 10. The conductive layer may include a gate electrode 61, a source electrode 62 and a drain electrode 63. The active layer 40 may include a channel region 41, a source transition region 42 and a drain transition region 44 located on two sides of the channel region 41, a source connection region 43 located on a side of the source transition region 42 away from the channel region 41, and a drain connection region 45 located on a side of the drain transition region 44 away from the channel region 41. The source connection region 43 is connected with the source electrode 62, and the drain connection region 45 is connected with the drain electrode 63. The source transition region 42 and the drain transition region 44 may each include a first sub-region 1, a second sub-region 2 and a third sub-region 3 connected sequentially, the first sub-region 1 is located on a side of the second sub-region 2 away from the channel region 41, the third sub-region 3 is located on a side of the second sub-region 2 close to the channel region 41, the thickness of the second sub-region 2 may be k times that of the channel region 41, and k is about 0.8 to 1.5. As such, since the thickness of the second sub-region 2 in the source transition region 42 and the thickness of the second sub-region 2 in the drain transition region 44 in the active layer 40 in the thin film transistor each is k times the thickness of the channel region 41, and k may be about 0.8 to 1.5, the partial missing of the second sub-region 2 is avoided, so that the conductivity of the source transition region 42 and the drain transition region 44 can be improved, and further, the current output capability of the thin film transistor can be improved.

Here, in the process of preparing the thin film transistor, the second sub-regions 2 in the source transition region 42 and the drain transition region 44 in the active layer are regions subject to double etchings and double conductorizations in the active layer.

In an exemplary embodiment, k may be set to 1 to 1.5, for example, k may be about 1, 1.5, 1.2, 1.25, 1.3, 1.35, 1.4, 1.45, 1.5, etc. In this way, the defect of the thin film transistor caused by two conductorizations can be more effectively prevented.

In an exemplary embodiment, as shown in FIGS. 2 and 3, both the thickness of the first sub-region 1 and the thickness of the third sub-region 3 may be equal to the thickness of the channel region 41.

In an exemplary embodiment, the thickness of the first sub-region 1 may be about 20 nm to 200 nm, the thickness of the second sub-region 2 may be about 16 nm to 300 nm, the thickness of the third sub-region 3 may be about 20 nm to 200 nm, and the thickness of the channel region 41 may be about 20 nm to 200 nm. Here, the embodiments of the present disclosure are not limited to this.

In an exemplary embodiment, the gate electrode 61, the source electrode 62 and the drain electrode 63 are made of the same material and disposed on the same layer. As such, the number of patterning processes can be reduced, the process time can be shortened, and the process cost can be reduced. Here, “disposed on the same layer” may mean that two (or more) structures are patterned through the same patterning process to form a structure, and materials of the structures may be the same or different. For example, the materials of the precursors of a plurality of structures disposed on the same layer are the same, and the final forming materials may be the same or different.

In an exemplary embodiment, the conductivity of the second sub-region 2 is greater than that of the first sub-region 1, and the conductivity of the second sub-region 2 is greater than that of the third sub-region 3. In this way, it is beneficial to improve the electrical characteristics of thin film transistors.

In an exemplary embodiment, the oxygen element content of the second sub-region 2 is less than the oxygen element content of the first sub-region 1, and the oxygen element content of the second sub-region 2 is less than the oxygen element content of the third sub-region 3. In this way, it is beneficial to improve the electrical characteristics of thin film transistors.

In an exemplary embodiment, the conductivity of the second sub-region 2 is greater than that of the source connection region 43, and the conductivity of the second sub-region 2 is greater than that of the drain connection region 45.

In an exemplary embodiment, the oxygen element content of the second sub-region 2 is less than the conductivity of the source connection region 43, and the oxygen element content of the second sub-region 2 is less than the oxygen element content of the drain connection region 45.

In an exemplary embodiment, as shown in FIG. 2, the thickness of the second sub-region 2 greater than the thickness of the channel region 41 (for example, k may be about 1 to 1.5) is taken as an example. The material of the first sub-region 1 and the material of the third sub-region 3 may both be a first conductor material, the first conductor material is obtained by performing one conductorization treatment on a first metal oxide film. The material of the second sub-region 2 may be a second conductor material, the second conductor material includes: a first sub-conductor material and a second sub-conductor material which are stacked, the first sub-conductor material is obtained by performing two conductorization treatments on the first metal oxide film, the second sub-conductor material is obtained by performing two conductorization treatments on a second metal oxide film, the second metal oxide film is disposed on a side of the first metal oxide film away from the base substrate 10, and the hardness of the oxygen element of the second metal oxide film is smaller than that of the first metal oxide film. In this way, the signal transmission capability can be enhanced, the current output capability of the thin film transistor can be improved, and the electrical performance of the thin film transistor can be improved.

In an exemplary embodiment, taking the thickness of the second sub-region 2 less than or equal to the thickness of the channel region 41 (for example k may be about 0.8 to 1) as an example, the material of the first sub-region 1 and the material of the third sub-region 3 may be a first conductor material, the first conductor material is obtained by performing one conductorization treatment on a first metal oxide film, and the material of the second sub-region 2 may be a third conductor material, the third conductor material is obtained by performing two conductorization treatments on the first metal oxide film. In this way, the signal transmission capability can be enhanced, the current output capability of the thin film transistor can be improved, and the electrical performance of the thin film transistor can be improved.

In an exemplary embodiment, the thickness of a second metal oxide layer in the second sub-region is smaller than the thickness of a first metal oxide layer in the second sub-region. For example, in the second sub-region, the thickness of the second sub-conductor material is smaller than the thickness of the first sub-conductor material.

In an exemplary embodiment, the first metal oxide film and the second metal oxide film may include, but not limited to adopt: metal oxides such as oxides containing indium and tin, oxides containing tungsten and indium, oxides containing tungsten, indium and zinc, oxides containing titanium and indium, oxides containing titanium, indium and tin, oxides containing indium and zinc, oxides containing silicon, indium and tin, oxides containing indium, gallium and zinc, etc. For example both the first metal oxide film and the second metal oxide film may be made of indium gallium zinc oxide (IGZO). For example, both the first metal oxide film and the second metal oxide film may be made of indium tin zinc oxide (ITZO). Here, the embodiments of the present disclosure are not limited to this.

In an exemplary embodiment, the width of the second sub-region may be less than the width of the first sub-region; alternatively, the width of the second sub-region may be less than the width of the third sub-region.

In an exemplary embodiment, as shown in FIG. 4, the source electrode 62 at least partially covers the second sub-region 2 of the source transition region 42; or the drain electrode 63 at least partially covers the second sub-region 2 of the drain transition region 44. In this way, the phenomenon that the first sub-region 1 is over-etched due to process errors can be avoided.

In an exemplary embodiment, as shown in FIG. 4, the second sub-region 2 of the source transition region 42 may include a first portion (not shown in the figure) covered by the source electrode 62 and a second portion (not shown in the figure) not covered by the source electrode 62, the width of the first portion is less than the width of the second portion; alternatively, the second sub-region 2 of the drain transition region 44 includes a third portion covered by the drain electrode 63 and a fourth portion not covered by the drain electrode 63, the width of the third portion is smaller than the width of the fourth portion.

In an exemplary embodiment, as shown in FIG. 4, the active layer 40 may further include a first region 46 located on a side of the source connection region 43 away from the channel region 41 and a second region 47 located on a side of the drain connection region 45 away from the channel region 41; wherein the width of the second sub-region 2 of the source transition region 52 is smaller than the width of the first region 46, or the width of the second sub-region 2 of the drain transition region 44 is smaller than the width of the second region 46.

Here, the width may refer to a dimensional characteristic along a first direction D1 that intersects a second direction D2, for example, the first direction D1 is perpendicular to the second direction D2, and the second direction D2 may refer to a direction perpendicular to the plane of the thin film transistor, or a thickness direction of the thin film transistor.

In an exemplary embodiment, as shown in FIGS. 2 and 4, the source electrode 62 is lapped on the first sub-region 1 of the source transition region 42 of the active layer 40, and connected with the source connection region 43 of the active layer 40 through a first via K1; and the drain electrode 63 is lapped on the first sub-region 1 of the drain transition region 44 of the active layer 40, and is connected with the drain connection region 45 of the active layer 40 through a second via K2. In this way, it is beneficial to improve the electrical characteristics of thin film transistors.

In an exemplary embodiment, as shown in FIGS. 2 and 3, a boundary of an orthographic projection of the active layer 40 on the base substrate 10 is within a range of a boundary of an orthographic projection of the shielding layer 20 on the base substrate 10.

In an exemplary embodiment, as shown in FIGS. 2 and 3, the shielding layer 20 may include a first shielding layer 201 and a second shielding layer 202 disposed at intervals, the boundary of the orthographic projection of the active layer 40 on the base substrate 10 is within a range of a boundary of an orthographic projection of the first shielding layer 201 on the base substrate, and the source electrode 62 is connected with the second shielding layer 202 through a third via K3. For example, the second shielding layer 202 may be configured to transmit gate signals, so that a thin film transistor with a double gate structure may be formed, i.e., the thin film transistor may include a lower transistor and an upper transistor with the same channel. Since a signal voltage value of a gate electrode (the second shielding layer 202) of the lower transistor is smaller than a signal voltage value of a gate electrode (the gate electrode 61) of the upper transistor, a negative bias degree of a threshold voltage of the lower transistor is smaller than a negative bias degree of a threshold voltage of the upper transistor, thereby reducing an overall negative bias degree of the thin film transistor, ensuring stability of the thin film transistor and ensuring uniformity of electrical characteristics of a transistor. For example, the first shielding layer 201 may be configured to perform shielding processing on the thin film transistor, so that the intensity of light irradiated onto the thin film transistor can be reduced, and the leakage current can be reduced. Accordingly, the influence of light on the characteristics of the thin film transistor can be reduced.

In an exemplary embodiment, the shielding layer may adopt any one or more of metallic materials such as silver (Ag), copper (Cu), aluminum (Al), titanium (Ti), and molybdenum (Mo), and may be a single-layer structure, or a multi-layer composite structure such as Ti/Al/Ti, etc. Here, the embodiments of the present disclosure are not limited to this.

In an exemplary embodiment, for the source transition region 42 and the drain transition region 44 of the active layer 40, the second sub-region 2 is formed by a first conductorization treatment and a second conductorization treatment, the first sub-region 1 is formed by the first conductorization treatment, the third sub-region 3 is formed by the second conductorization treatment, and the channel region 41 is formed during the self-aligned second conductorization treatment. In this way, since the second sub-region 2 is formed by two conductorization treatments, the conductivity of the second sub-region 2 can be improved, which is beneficial to improve the electrical characteristics of pixel drive circuits. Moreover, since the channel region is formed during the self-aligned second conductorization treatment, the alignment accuracy between the gate electrode and the lower channel region can be improved, and the electrical characteristics of the thin film transistor can be improved.

In an exemplary embodiment, the thin film transistor according to an exemplary embodiment of the present disclosure may be applied to a display substrate with a pixel drive circuit, such as an OLED, a quantum dot display (QLED), a light emitting diode display (Micro LED or Mini LED), or a quantum dot light emitting diode display (QDLED) etc. Here, the embodiments of the present disclosure are not limited to this.

The following is an exemplary description by a preparation process of a thin film transistor. A “patterning process” mentioned in the present disclosure includes coating with a photoresist, mask exposure, development, etching, photoresist stripping, and other treatments for a metal material, an inorganic material, or a transparent conductive material, and includes coating with an organic material, mask exposure, development, and other treatments for an organic material. Deposition may be any one or more of sputtering, evaporation, and chemical vapor deposition. Coating may be any one or more of spray coating, spin coating, and ink-jet printing. Etching may be any one or more of dry etching and wet etching, which is not limited in present disclosure. A “thin film” refers to a layer of thin film made of a material on a base substrate through a process such as deposition, coating, etc. If the “thin film” does not need a patterning process in an entire manufacturing process, the “thin film” may also be called a “layer”. If the “thin film” needs a patterning process in an entire manufacturing process, it is called a “thin film” before the patterning process, and called a “layer” after the patterning process. The “layer” after the patterning process includes at least one “pattern”. “A and B are disposed on the same layer” in the present disclosure means that A and B are formed simultaneously through the same patterning processes, and the “thickness” of the film layer is the dimension of the film layer in a direction perpendicular to the thin film transistor. In an exemplary embodiment of the present disclosure, “an orthographic projection of B is within a range of an orthographic projection of A” or “an orthographic projection of A includes an orthographic projection of B” refers to that a boundary of the orthographic projection of B falls within a range of a boundary of the orthographic projection of A, or the boundary of the orthographic projection of A is overlapped with the boundary of the orthographic projection of B.

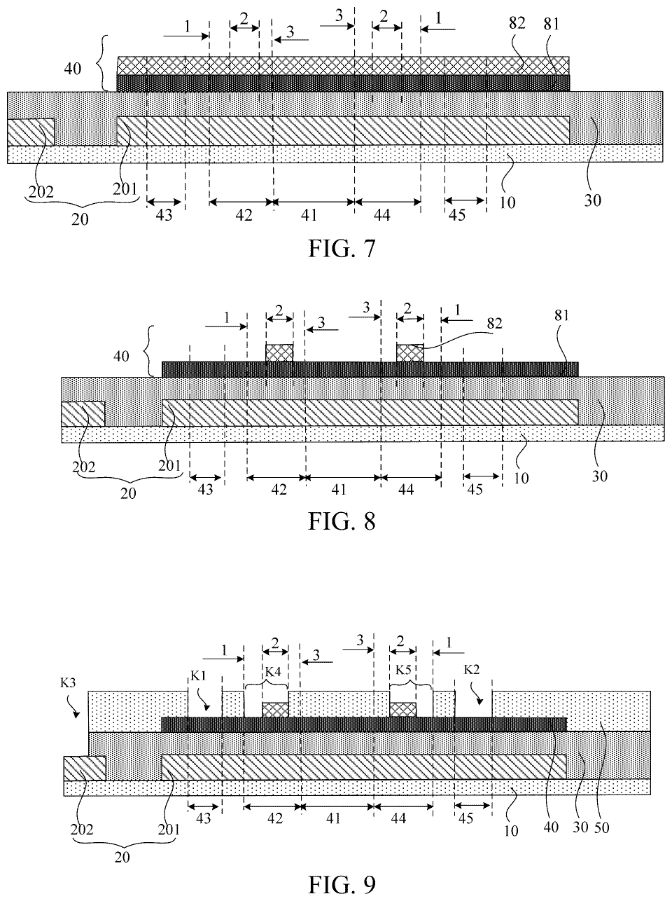

In an exemplary embodiment, taking the structure of the thin film transistor shown in FIG. 2 as an example, as shown in FIG. 5 to FIG. 12, the preparation process of the thin film transistor may include the following operations.

(1) A pattern of a shielding layer is formed.

In an exemplary embodiment, forming the pattern of the shielding layer may include sequentially depositing a first metal film on the base substrate 10, patterning the first metal film through a patterning process to form the pattern of the shielding layer 20 on the base substrate 10.

In an exemplary embodiment, as shown in FIG. 5, taking a case where the shielding layer 20 may include a first shielding layer 201 and a second shielding layer 202 as an example, the first metal film is patterned through a halftone patterning process, which may include: first, coating a layer of photoresist on the first metal film, exposing the photoresist by a mask, and forming a pattern of photoresist after development. The pattern of the photoresist may include an unexposed region and a fully exposed region, the unexposed region includes the positions where the patterns of the first shielding layer 201 and the second shielding layer 202 are located, the photoresist of the unexposed region has a first thickness, the photoresist of the fully exposed region is completely removed, to form the pattern of the shielding layer 20 on the base substrate 10.

In an exemplary embodiment, the thickness of the first metal film may be about 100 nm (nanometer) to 1000 nm. Here, the embodiments of the present disclosure are not limited to this.

(2) A pattern of an active layer is formed.

In an exemplary embodiment, as shown in FIGS. 6 to 8, forming the pattern of the active layer may include: on the base substrate 10 on which the aforementioned patterns are formed, depositing a first insulating film, a first metal oxide film 81, and a second metal oxide film 82 sequentially, patterning the first metal oxide film 81 and the second metal oxide film 82 through a halftone patterning process, to form a buffer layer 30 covering the pattern of the shielding layer 20 and form the pattern of the active layer 40 on the buffer layer 30.

In an exemplary embodiment, as shown in FIGS. 6 to 8, the first metal oxide film 81 and the second metal oxide film 82 are patterned through a halftone patterning process, which can include: first, coating a layer of photoresist on the second metal oxide film 82, exposing the photoresist by a halftone mask, and forming a pattern of photoresist after development. The pattern of the photoresist includes an unexposed region, a partially exposed region and a fully exposed region. The unexposed region includes the positions where a channel region 41, a source transition region 42, a drain transition region 44, a source connection region 43 and a drain connection region 45 in the active layer 40 are located. The photoresist of the unexposed region has a first thickness. The partially exposed region includes the positions where the second sub-region 2 in the source transition region 42 and the second sub-region 2 in the drain transition region 44 are located, and the photoresist of the partially exposed region has a second thickness, which is smaller than the first thickness. The other region is the fully exposed region, and the photoresist of the fully exposed region is completely removed to expose a surface of the second metal oxide thin film 82. Subsequently, the first metal oxide thin film 81 and the second metal oxide thin film 82 in the fully exposed region are removed by a first etching process. Subsequently, the photoresist of the partially exposed region is removed by an ashing process, to expose the surface of the second metal oxide thin film 82 in the partially exposed region. After that, the second metal oxide thin film 82 in the partially exposed region is removed by a second etching process, to expose the first metal oxide thin film 81 in the partially exposed region. Finally, the remaining photoresist is stripped off to form the pattern of the active layer 40 on the base substrate. Thus, a layer of metal oxide film can be formed in positions where the channel region 41, the first sub-region 1 and the third sub-region 3 in the source transition region 42, the first sub-region 1 and the third sub-region 3 in the drain transition region 44, the source connection region 43 and the drain connection region 45 in the active layer 40 are located, double layers of metal oxide films are formed in positions where the second sub-region 2 in the source transition region 42 and the second sub-region 2 in the drain transition region 44 are located. In this way, since there are thicker metal oxide films in the positions where the second sub-region 2 in the source transition region 42 and the second sub-region 2 in the drain transition region 44 are located, the etching resistance of the positions where the second sub-region 2 in the source transition region 42 and the second sub-region 2 in the drain transition region 44 are located can be increased, so that the metal oxide films in the second sub-region 2 in the source transition region 42 and the second sub-region 2 in the drain transition region 44 can be prevented from being etched through in a subsequent process, and the conductivity can be improved.

In an exemplary embodiment, the deposition process of the second metal oxide film 82 is different from the deposition process of the first metal oxide film 81. For example, the oxygen element content of the second metal oxide film 82 is greater than the oxygen element content of the first metal oxide film 81, and the power of the second metal oxide film 82 is less than the power of the first metal oxide film 81, so that there may be an obvious film quality difference between the second metal oxide film 82 and the first metal oxide film 81. Relatively, the hardness of the first metal oxide film 81 is greater than that of the second metal oxide film 82. Thus, on the one hand, the second metal oxide film 82 on the first metal oxide film 81 can be etched away by performing a second etching process for proper time, and on the other hand, the etching resistance of the first metal oxide film 81 can be increased to avoid partial missing of the first metal oxide film 81. Here, the power refers to a sputtering power used in the deposition process when the metal oxide film is deposited.

In an exemplary embodiment, the oxygen element content of the second metal oxide film may be about 30% to 50%, and the oxygen element content of the first metal oxide film may be about 20% to 30%. Here, the embodiments of the present disclosure are not limited to this.

In an exemplary embodiment, the power of the second metal oxide film may be about 4 kw (kilowatt) to 6 kw, and the power of the first metal oxide film may be about 8 kw to 14 kw. Here, the embodiments of the present disclosure are not limited to this.

In an exemplary embodiment, the first metal oxide film and the second metal oxide film may include, but are not limited to adopt: metal oxides such as oxides containing indium and tin, oxides containing tungsten and indium, oxides containing tungsten, indium and zinc, oxides containing titanium and indium, oxides containing titanium, indium and tin, oxides containing indium and zinc, oxides containing silicon, indium and tin, oxides containing indium, gallium and zinc, etc. For example, both the first metal oxide film and the second metal oxide film may be made of indium gallium zinc oxide (IGZO). For example, both the first metal oxide film and the second metal oxide film may be made of indium tin zinc oxide (ITZO). Here, the embodiments of the present disclosure are not limited to this.

In an exemplary embodiment, after the pattern of the active layer is formed, the thickness of the first metal oxide film and the thickness of the second metal oxide film may be about 20 nm to 200 nm. Here, the embodiments of the present disclosure are not limited to this.

In an exemplary embodiment, a thickness of the first insulating film may be about 200 nm to 1000 nm. Here, the embodiments of the present disclosure are not limited to this.

(3) A pattern of a gate insulating (GI) layer is formed.

In an exemplary embodiment, as shown in FIG. 9, forming the pattern of the gate insulating (GI) layer 50 may include: on the base substrate 10 on which the aforementioned patterns are formed, depositing a second insulating film sequentially, and patterning the second insulating film through a halftone patterning process to form the pattern of the gate insulating (GI) layer 50 and a pattern of a plurality of vias opened on the gate insulating (GI) layer 50. The pattern of the plurality of vias includes at least a first via K1, a second via K2, a third via K3, a fourth via K4 and a fifth via K5.

In an exemplary embodiment, as shown in FIG. 9, patterning the second insulating film through a halftone patterning process may include: first, coating a layer of photoresist on the second insulating film, exposing the photoresist by a halftone mask, and forming a pattern of photoresist after development, the pattern of the photoresist includes an unexposed region, a partially exposed region, and a fully exposed region. The fully exposed region includes a position where the pattern of the third via K3 is located, the partially exposed region includes positions where the patterns of the first via K1, the second via K2, the fourth via K4 and the fifth via K5 are located, the other regions are the unexposed region. The photoresist of the unexposed region has a first thickness, the photoresist of the partially exposed region has a second thickness, and the second thickness is smaller than the first thickness. Subsequently, the second insulating film and a first insulating layer in the fully exposed region are removed by a first etching process, and the pattern of the third via K3 pattern is formed, so that the third via K3 exposes the second shielding layer 202, and the source electrode 62 formed subsequently may be connected with the second shielding layer 202 through the third via K3. Then, the photoresist of the partially exposed region is removed by an ashing process, to expose the second insulating film in the partially exposed region. After that, the second insulating film in the partially exposed region is removed by a second etching process to form the patterns of the first via K1, the second via K2, the fourth via K4, and the fifth via K5, so that the first via K1, the second via K2, the fourth via K4, and the fifth via K5 expose the active layer 40 for subsequent second conductorization treatment. Finally, the remaining photoresist is stripped off to form the pattern of the gate insulating (GI) layer 50 and the pattern of the plurality of vias disposed on the gate insulating (GI) layer 50.

In an exemplary embodiment, the pattern of the plurality of vias includes at least the first via K1, the second via K2, the third via K3, the fourth via K4, and the fifth via K5. The first Via K1 is located at a position where the source connection region 43 in the active layer 40 is located, and exposes the surface of the source connection region 43 in the active layer 40. The first Via K1 is configured to connect a source electrode 62 of a subsequently formed thin film transistor with the source connection region 43. The second via K2 is located at a position where the drain connection region 45 in the active layer 40 is located, and exposes the surface of the drain connection region 45 in the active layer 40. The second via K2 is configured to connect a drain electrode 63 of the subsequently formed thin film transistor with the drain connection region 45. The third via K3 is located at a position where the second shielding layer 202 in the shielding layer 20 is located, and exposes the surface of the second shielding layer 202 in the shielding layer 20. The third via K3 is configured to connect the source electrode 62 of the subsequently formed thin film transistor with the second shielding layer 202 in the shielding layer 20. The fourth via K4 is located at positions where the first sub-region 1 and the second sub-region 2 in the source transition region 42 in the active layer 40 are located, and exposes the surfaces of the first sub-region 1 and the second sub-region 2 in the source transition region 42 in the active layer 40 for subsequent conductorization treatment. The fifth via K5 is located at positions where the first sub-region 1 and the second sub-region 2 in the drain transition region 44 in the active layer 40 are located, and exposes the surfaces of the first sub-region 1 and the second sub-region 2 in the drain transition region 44 in the active layer 40 for subsequent conductorization treatment.

In an exemplary embodiment the gate insulating (GI) layer 50 located at a position where the active layer 40 is located covers a portion of the active layer 40.

In an exemplary embodiment, the thickness of the second insulating film may be about 100 nm to 500 nm. Here, the embodiments of the present disclosure are not limited to this.

(4) A first conductorization treatment is performed.

In an exemplary embodiment, as shown in FIG. 9, the first conductorization treatment is performed after the pattern of the plurality of vias opened on the gate insulating (GI) layer 50 is formed. The first conductorization treatment may include: on the base substrate on which the aforementioned patterns are formed, the first conductorization treatment is performed on a portion of the active layer 40 not covered by the gate insulating (GI) layer 50, that is, the first conductorization treatment is performed on the active layer at the positions where the first sub-region 1 of the source transition region 42, the first sub-region 1 of the drain transition region 44, the source connection region 43, and the drain connection region 45 are located, to form the first sub-region 1 of the source transition region 42, the first sub-region 1 of the drain transition region 44, the source connection region 43 and the drain connection region 45 of the active layer, and a conductorization treatment is performed on the second sub-region 2 of the source transition region 42 and the second sub-region 2 of the drain transition region 44 of the active layer, to form second sub-regions 2 after one conductorization treatment.

(5) A pattern of a conductive layer is formed.

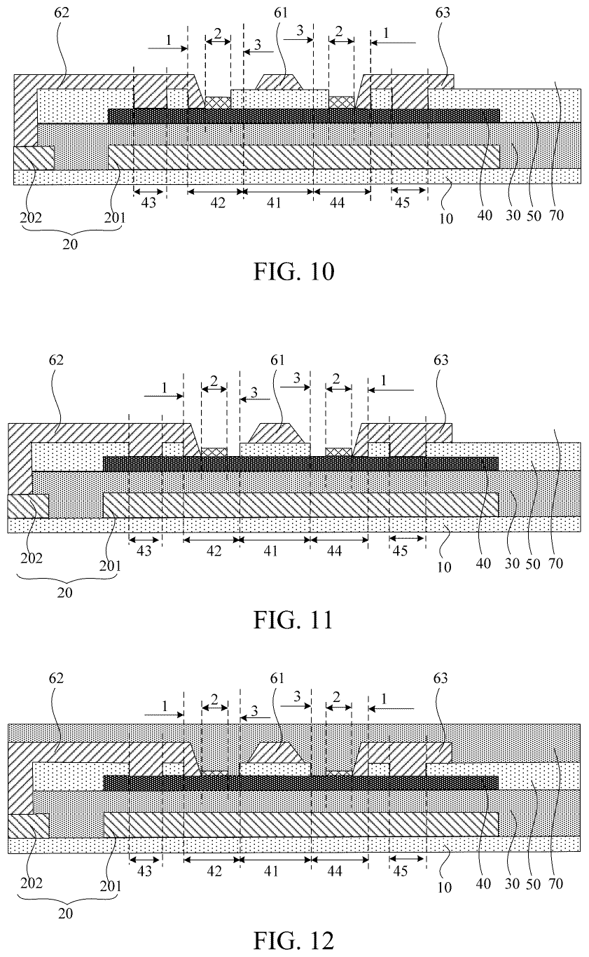

In an exemplary embodiment, as shown in FIG. 10, forming the pattern of the conductive layer may include: depositing a second metal film on the base substrate on which the aforementioned patterns are formed, coating a layer of photoresist on the second metal film, and forming a pattern of photoresist by mask, exposure and development, etching the second metal film using a first etching process to form the pattern of the conductive layer, and remaining the photoresist on the conductive layer. The pattern of the conductive layer may include at least the patterns of the gate electrode 61, the source electrode 62, and the drain electrode 63.

In an exemplary embodiment, as shown in FIG. 10, the source electrode 62 is connected with the source connection region 43, on which the conductorizaiton treatment has been performed, of the active layer 40 through the first via K1, a first terminal of the source electrode 62 is lapped on the first sub-region 1 of the source transition region 42, on which the conductorizaiton treatment has been performed, of the active layer 40, and a second terminal of the source electrode 62 is connected with the second shielding layer 202 through the third via K3.

In an exemplary embodiment, as shown in FIG. 10, the drain electrode 63 is connected with the drain connection region 45, on which the conductorizaiton treatment has been performed, of the active layer 40 through the second via K2, and a first terminal of the source electrode 62 is lapped on the first sub-region 1 of the drain transition region 44, on which the conductorizaiton treatment has been performed, of the active layer 40.

In an exemplary embodiment, a thickness of the second metal film is about 100 nm to 1000 nm. Here, the embodiments of the present disclosure are not limited to this.

(6) A second etching treatment is performed.

In an exemplary embodiment, as shown in FIG. 11, the second etching treatment may include: self-aligned downward etching the gate insulating (GI) layer 50 through the second etching process using the pattern of the conductive layer and the photoresist remaining on the conductive layer as a mask, to remove the gate insulating (GI) layer 50 covered by the third sub-region 3 of the source transition region 42 and the third sub-region 3 of the drain transition region 44 of the active layer.

In an exemplary embodiment, as shown in FIG. 11, the boundary of the orthographic projection of the gate electrode 61 on the base substrate 10 is within a range of the boundary of the orthographic projection of the gate insulating (GI) layer 50 on the base substrate, and the boundary of the orthographic projection of the channel region 41 of the active layer on the base substrate 10 is within the range of the boundary of the orthographic projection of the gate insulating (GI) layer 50 on the base substrate.

(7) A second conductorization treatment is performed.

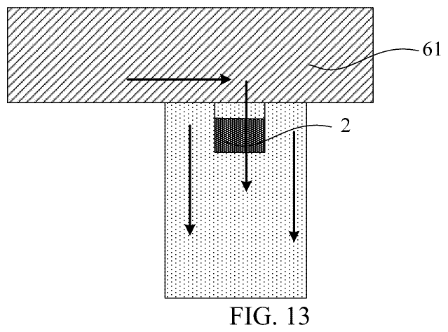

In an exemplary embodiment, as shown in FIGS. 11 and 12, the second conductorization treatment may include: using the gate insulating (GI) layer 50, a pattern of a conductive layer disposed on the gate insulating (GI) layer 50 (e.g., the pattern of the conductive layer may include at least the patterns of the gate electrode 61, the source electrode 62 and the drain electrode 63), and the photoresist remaining on the conductive layer as a mask, a conductorization treatment is performed on another part of the active layer 40 that is not covered by the gate insulating (GI) layer 50, that is, the conductorization treatment is performed on positions where the unconductorized channel region 41 of the active layer 40, the unconductorized third sub-region 3 of the source transition region 42 of the active layer 40, and the unconductorized third sub-region 3 of the drain transition region 44 of the active layer 40 are located to form the channel region 41 of the active layer 40, the third sub-region 3 of the source transition region 42, and the third sub-region 3 of the drain transition region 44 of the active layer 40; and a conductorization treatment is performed on positions where the second sub-region 2 of the source transition region 42 after one conductorization treatment and the second sub-region 2 of the drain transition region 44 after one conductorization treatment are located to form the second sub-region 2 of the source transition region 42 after two conductorization treatments and the second sub-region 2 of the drain transition region 44 after two conductorization treatments. The remaining photoresist is stripped off.

Here, since the second conductorization treatment is a self-aligned conductorization treatment using the gate insulating (GI) layer 50, the pattern of the conductive layer, and the photoresist remaining on the conductive layer as a mask, the width of the channel finally formed is substantially the same as that of the gate electrode 61. In this way, the alignment accuracy between the gate electrode 61 and the lower channel region can be improved, and the electrical characteristics of the thin film transistor are greatly improved.

In an exemplary embodiment, the active layer is subjected to two conductorization treatments, so that the active layer forms five regions: a channel region 41, a source transition region 42 and a drain transition region 44 located on two sides of the channel region 41, a source connection region 43 located on a side of the source transition region 42 away from the channel region 41, and a drain connection region 45 located on a side of the drain transition region 44 away from the channel region 41. Herein, the boundary of the orthographic projection of the channel region 41 on the base substrate substantially coincides with the boundary of the orthographic projection of the gate electrode 61 on the base substrate.

In an exemplary embodiment, since two conductorization treatments and two etching treatments are employed, the region of the first conductorization treatment and the region of the second conductorization treatment have an overlapping region, i.e., a region at the position where the second sub-region 2 is located. Since there are thicker metal oxide films in the positions where the second sub-region 2 in the source transition region 42 and the second sub-region 2 in the drain transition region 44 in the active layer 40 are located, the etching resistance of the second sub-region 2 in the source transition region 42 and the second sub-region 2 in the drain transition region 44 can be increased, to prevent the metal oxide films in the second sub-region 2 in the source transition region 42 and the second sub-region 2 in the drain transition region 44 from being etched through. Accordingly, the conductivity can be improved.

In an exemplary embodiment, since the second sub-region 2 in the source transition region 42 and the second sub-region 2 in the drain transition region 44 in the active layer 40 are subjected to two conductorization treatments, the second sub-region 2 in the source transition region 42 and the second sub-region 2 in the drain transition region 44 in the active layer 40 that are subjected to two conductorization treatments have lower resistance and stronger conductivity, the conductivity of the second sub-region 2 is greater than that of the first sub-region 1, and the conductivity of the second sub-region 2 is greater than that of the third sub-region 3. In this way, it is beneficial to improve the electrical characteristics of thin film transistors.

In an exemplary embodiment, the second sub-region 2 in the source transition region 42 and the second sub-region 2 in the drain transition region 44 in the active layer 40 are subjected to two conductorization treatments, so that the second sub-region 2 in the source transition region 42 and the second sub-region 2 in the drain transition region 44 in the active layer 40 that are subjected to two conductorization treatments are subjected to two helium (He) plasma treatments, to further reduce the oxygen element content in the film layer. Accordingly, the oxygen element content of the second sub-region 2 is less than that of the first sub-region 1, and the oxygen element content of the second sub-region 2 is less than that of the third sub-region 3. In this way, it is beneficial to improve the electrical characteristics of thin film transistors.

In an exemplary embodiment, the second sub-region 2 in the source transition region 42 and the second sub-region 2 in the drain transition region 44 in the active layer 40 are subjected to two conductorization treatments, the source connection region 43 and the drain connection region 45 in the active layer 40 are only subjected to first conductorization treatment, so that the conductivity of the second sub-region 2 is greater than that of the source connection region 43, and the conductivity of the second sub-region 2 is greater than that of the drain connection region 45. The oxygen element content of the second sub-region 2 is smaller than the oxygen element content of the source connection region 43, and the oxygen element content of the second sub-region 2 is smaller than the oxygen element content of the drain connection region 45.

In an exemplary embodiment, during the two conductorization treatments, two etching treatments are performed on the gate insulating (GI) layer 50. The over-etching in the etching process will etch away part of the thickness of the second sub-region 2 in the source transition region 42 and part of the thickness of the second sub-region 2 in the drain transition region 44 in the active layer 40. Therefore, the second metal oxide layer 81 in the second sub-region 2 will become thinner or even be completely missing after act 7, compared with the pattern of the active layer formed in act 2. Accordingly, after act 7, when the second metal oxide layer 81 in the second sub-region 2 becomes thinner only, for example, the thickness of the second metal oxide layer 81 in the second sub-region 2 is smaller than the thickness of the first metal oxide layer 82 in the second sub-region 2, the material of the second sub-region 2 may be a second conductor material. The second conductor material includes a first sub-conductor material and a second sub-conductor material which are stacked. The first sub-conductor material is obtained by performing two conductorization treatments on the first metal oxide film, and the second sub-conductor material is obtained by performing two conductorization treatments on the second metal oxide film, so that the thickness of the second sub-region 2 is greater than the thickness of the channel region 41 (for example, k may be about 1 to 1.5). After act 7, when the second metal oxide layer 81 in the second sub-region 2 is completely missing, the material of the second sub-region 2 may be a third conductor material, which is obtained by performing two conductorization treatments on the first metal oxide film, so that the thickness of the second sub-region 2 is less than or equal to the thickness of the channel region 41 (for example, k may be about 0.8 to 1). In this way, when the pattern of the active layer is formed, two different metal oxide films are formed in the second sub-region 2 in act 2, so that the second sub-region 2 is thicker, then the partial missing of the second sub-region can be avoided in the finally formed thin film transistor after the double etching treatments and the double conductorization treatments, In this way, the signal transmission capability can be enhanced, the current output capability of the thin film transistor can be improved, and the electrical performance of the thin film transistor can be improved.

In an exemplary embodiment, due to the act 2, there are thicker metal oxide films in the positions where the second sub-region 2 in the source transition region 42 and the second sub-region 2 in the drain transition region 44 in the active layer 40 are located, therefore, the thickness of the second sub-region 2 in the source transition region 42 and the drain transition region 44 in the finally formed active layer 40 may be k times the thickness of the channel region 41, and k may be about 0.8 to 1.5. Thus, as shown in FIG. 13, partial missing of the second sub-region 2 is avoided, so that the conductivity of the source transition region 42 and the drain transition region 44 can be improved, and further, the current output capability of the thin film transistor can be improved.

(8) A pattern of a passivation (Pas) layer is formed.

In an exemplary embodiment, as shown in FIG. 12, forming the pattern of the passivation layer may include: depositing a third insulating film on the base substrate on which the aforementioned patterns are formed, to form the pattern of the passivation layer 70 covering the aforementioned structures.

In an exemplary embodiment, the thickness of the third insulating film may be about 200 nm to 1000 nm. Here, the embodiments of the present disclosure are not limited to this.

In an exemplary embodiment, the shielding layer and the conductive layer may be made of a metal material, such as any one or more of silver (Ag), copper (Cu), aluminum (Al), titanium (Ti) and molybdenum (Mo), or alloy of the above metals, such as aluminum neodymium alloy (AlNd) or molybdenum niobium alloy (MoNb), and may have a single-layer structure or a multi-layer composite structure, such as Ti/Al/Ti. Here, the embodiments of the present disclosure are not limited to this.

In an exemplary embodiment, the buffer layer, the gate insulating layer, and the passivation layer may adopt any one or more of silicon oxide (SiOx), silicon nitride (SiNx), and silicon oxynitride (SiON), and may be a single-layer, multi-layers, or a composite layer. Here, the embodiments of the present disclosure are not limited to this.

In an exemplary embodiment, the base substrate may be a flexible base substrate, or may be a rigid base substrate. For example, the rigid base substrate may include, but is not limited to, a material such as glass or quartz. For example, the flexible base substrate may include, but is not limited to, a material such as polyimide (PI) or polyethylene terephthalate (PET), the flexible base substrate may be a single-layer structure, or may be a stacked structure formed by an inorganic material layer and a flexible material layer. Here, the embodiments of the present disclosure are not limited to this.

An exemplary embodiment of the present disclosure further provides a preparation method of a thin film transistor. The thin film transistor is the thin film transistor according to one or more exemplary embodiments described above.

In an exemplary embodiment, a preparation method of the thin film transistor may include the following acts S1 and S2.

In act S1, a shielding layer, a buffer layer and an active layer are formed sequentially on the base substrate.

In act S2, a gate insulating layer and a conductive layer are sequentially formed on the active layer, a channel region, a source transition region and a drain transition region located on two sides of the channel region, a source connection region located on a side of the source transition region away from the channel region, and a drain connection region located on a side of the drain transition region away from the channel region are formed in the active layer through two conductorization treatments; the conductive layer may include a gate electrode, a source electrode, and a drain electrode; the source connection region is connected with the source electrode, and the drain connection region is connected with the drain electrode; both the source transition region and the drain transition region may include: a first sub-region, a second sub-region and a third sub-region connected sequentially, the first sub-region is located on a side of the second sub-region away from the channel region, and the third sub-region is located on a side of the second sub-region close to the channel region, the thickness of the first sub-region and the thickness of the third sub-region are both equal to the thickness of the channel region, the thickness of the second sub-region is k times the thickness of the channel region, and k may be about 0.8 to 1.5.

In an exemplary embodiment, the act S1 may include the following acts S11 and S12.

In act S11, a shielding layer and a buffer layer are formed sequentially on the base substrate.

In act S12, two layers of metal oxide films are formed on the buffer layer, the two layers of metal oxide films are patterned to form the active layer, and the two layers of metal oxide films may include a first metal oxide film and a second metal oxide film which are stacked, the oxygen element content of the second metal oxide film is greater than the oxygen element content of the first metal oxide film, and the power of the second metal oxide film is less than the power of the first metal oxide film.

In an exemplary embodiment, the act S2 may include the following acts S21 to S25.

In act S21, a gate insulating layer is formed on the active layer.

In act S22, a first conductorization treatment is performed on the active layer not covered by the gate insulating layer, to form a first sub-region of the source transition region, a first sub-region of the drain transition region, a source connection region and a drain connection region in the active layer.

In act S23, a conductive layer is formed on the gate insulating layer.

In act S24, the gate insulating layer of the source transition region and the gate insulating layer of the drain transition region are removed by using a self-aligned etching to expose the unconductorized third sub-region of the drain transition region and the unconductorized third sub-region of the source transition region.

In act S25, a second conductorization treatment is performed on the active layer not covered by the gate insulating layer to form a channel region, a second sub-region and a third sub-region of the source transition region, and a second sub-region and a third sub-region of the drain transition region.

The preparation process of the thin film transistor has been described in detail in the previous embodiments of the thin film transistor. The technical details not disclosed in the embodiments of the preparation method of the thin film transistor of the present disclosure will be understood by those skilled in the art with reference to the description in embodiments of the thin film transistor of the present disclosure, and will not be repeated here.

An embodiment of the present disclosure provides a display substrate, which may include a thin film transistor in the above one or more embodiments.

In an exemplary embodiment, on a plane perpendicular to the display substrate, the display substrate may include a drive circuit layer disposed on a base substrate, a light emitting structure layer disposed on a side of the drive circuit layer away from the base substrate, and an encapsulation structure layer disposed on a side of the light emitting structure layer away from the base substrate. In some possible implementations, the display substrate may include other film layers such as a touch structure layer and the like. Here, the embodiments of the present disclosure are not limited to this.

In an exemplary embodiment, the drive circuit layer of each sub-pixel may include a plurality of transistors and a storage capacitor forming the pixel drive circuit, and at least one of the plurality of transistors may be a thin film transistor according to the above one or more embodiments. For example, the pixel drive circuit may adopt a 3T1C, 4T1C, 5T1C, 5T2C, 6T1C, 7T1C, 8T1C structure or the like. Here, the embodiments of the present disclosure are not limited to this.

In an exemplary embodiment, the light emitting structure layer may include an anode, a pixel definition layer, an organic light emitting layer and a cathode. The anode is connected with a drain electrode of the drive transistor through a via, the organic light emitting layer is connected with the anode, the cathode is connected with the organic light emitting layer, and the organic light emitting layer emits light of a corresponding color under the drive of the anode and the cathode. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer. Here, the embodiments of the present disclosure are not limited to this.

In an exemplary embodiment, the organic light emitting layer may include an emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In an exemplary embodiment, one or more of hole injection layers, hole transport layers, electron block layers, hole block layers, electron transport layers, and electron injection layers of all sub-pixels may be a common layer communicated together. Emitting layers of adjacent sub-pixels may be overlapped slightly, or may be isolated. Here, the embodiments of the present disclosure are not limited to this.

In an exemplary embodiment, the display substrate according to the exemplary embodiment of the present disclosure may include, but is not limited to, an OLED display substrate, a QLED display substrate, a light emitting diode display (Micro LED or Mini LED), a quantum dot light emitting diode (QDLED) display substrate, or the like. Here, the embodiments of the present disclosure are not limited to this.

In addition, the display substrate according to the embodiment of the present disclosure may include other necessary components and structures, such as gate lines, data lines, pixel electrodes, common electrodes and the like, in addition to the structures provided above. Those skilled in the art can design and supplement the display substrate accordingly according to the type of the display substrate, which will not be described here.

The above description of the embodiments of the display substrate is similar to the above description of the embodiments of the thin film transistor, and the embodiments of the display substrate have similar beneficial effects as the embodiments of the thin film transistor. Technical details undisclosed in the embodiments of the display substrate of the present disclosure may be understood by those skilled in the art with reference to the descriptions in the embodiments of the thin film transistor of the present disclosure, which will not be described here.

An embodiment of the present disclosure also provides a display apparatus, which may include a display substrate according to the above one or more embodiments.

In an exemplary embodiment, the display apparatus may include, but is not limited to, a display apparatus with a pixel drive circuit, such as an OLED display apparatus, a QLED display apparatus, a light emitting diode (Micro LED or Mini LED) display apparatus, or a quantum dot light emitting diode (QDLED) display apparatus. For example, taking an OLED display apparatus used as the display apparatus as an example, the display apparatus may be a 48-inch television (TV). Here, the embodiments of the present disclosure are not limited to this.

In an exemplary embodiment, the display apparatus may include, but is not limited to, any product or component having a display function, such as a mobile phone, a tablet computer, a television, a display, a notebook computer, a digital photo bezel, or a navigator. Here, there is no limitation on a type of the display apparatus in the embodiments of the present disclosure. Other essential components included by the display apparatus which should be understood to be included in the display apparatus by those of ordinary skill in the art will not be described repeatedly herein, and should not be taken as a limitation on the present disclosure.

The above description of the embodiments of the display apparatus is similar to the above description of the embodiments of the thin film transistor and display substrate, and the embodiments of the display apparatus have similar beneficial effects as the embodiments of the thin film transistor and display substrate. Technical details undisclosed in the embodiments of the display apparatus of the present disclosure may be understood by those skilled in the art with reference to the description in the embodiments of the thin film transistor and the display substrate of the present disclosure, which will not be repeated here.

Although the implementations of the present disclosure are disclosed above, the above contents are only implementations for easily understanding the present disclosure and not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A thin film transistor, comprising: a base substrate, and a shielding layer, a buffer layer, an active layer, a gate insulating layer and a conductive layer that are stacked on the base substrate; wherein
the conductive layer comprises a gate electrode, a source electrode and a drain electrode;
the active layer comprises a channel region, a source transition region and a drain transition region that are located at two sides of the channel region, a source connection region located on a side of the source transition region away from the channel region, and a drain connection region located on a side of the drain transition region away from the channel region;
the source connection region is connected with the source electrode, and the drain connection region is connected with the drain electrode;
the source transition region and the drain transition region each comprise: a first sub-region, a second sub-region and a third sub-region sequentially connected, the first sub-region is located on a side of the second sub-region away from the channel region, the third sub-region is located on a side of the second sub-region close to the channel region, a thickness of the second sub-region is k times a thickness of the channel region, k is 0.8 to 1.5.

2. The thin film transistor according to claim 1, wherein a thickness of the first sub-region and a thickness of the third sub-region are both equal to the thickness of the channel region.

3. The thin film transistor according to claim 1, wherein a conductivity of the second sub-region is greater than that of the first sub-region, and the conductivity of the second sub-region is greater than that of the third sub-region.

4. The thin film transistor according to claim 1, wherein an oxygen element content of the second sub-region is less than that of the first sub-region, and the oxygen element content of the second sub-region is less than that of the third sub-region.

5. The thin film transistor according to claim 1, wherein a conductivity of the second sub-region is greater than that of the source connection region, and the conductivity of the second sub-region is greater than that of the drain connection region.

6. The thin film transistor according to claim 1, wherein an oxygen element content of the second sub-region is less than that of the source connection region, and the oxygen element content of the second sub-region is less than that of the drain connection region.

7. The thin film transistor according to claim 1, wherein, a material of the first sub-region and a material of the third sub-region are both a first conductor material, the first conductor material is obtained by performing one conductorization treatment on a first metal oxide film; a material of the second sub-region comprises: a second conductor material or a third conductor material, the second conductor material comprises: a first sub-conductor material and a second sub-conductor material which are stacked, the first sub-conductor material is obtained by performing two conductorization treatments on the first metal oxide film, the second sub-conductor material is obtained by performing two conductorization treatments on a second metal oxide film, the third conductor material is obtained by performing two conductorization treatments on the first metal oxide film, and hardness of the second metal oxide film is smaller than that of the first metal oxide film.

8. The thin film transistor according to claim 7, wherein a thickness of a second metal oxide layer in the second sub-region is smaller than a thickness of a first metal oxide layer in the second sub-region.

9. The thin film transistor according to claim 7, wherein the first metal oxide film and the second metal oxide film are both formed by indium gallium zinc oxide (IGZO).

10. The thin film transistor according to claim 1, wherein a width of the second sub-region is smaller than a width of the first sub-region; or, a width of the second sub-region is smaller than a width of the third sub-region.

11. The thin film transistor according to claim 1, wherein the source electrode at least partially covers a second sub-region of the source transition region; or, the drain electrode at least partially covers a second sub-region of the drain transition region.

12. The thin film transistor according to claim 11, wherein the second sub-region of the source transition region comprises: a first portion covered by the source electrode, and a second portion not covered by the source electrode, a width of the first portion is smaller than a width of the second portion; or, the second sub-region of the drain transition region comprises a third portion covered by the drain electrode, and a fourth portion not covered by the drain electrode, and a width of the third portion is smaller than a width of the fourth portion.

13. The thin film transistor according to claim 11, wherein the active layer further comprises: a first region located on a side of the source connection region away from the channel region, and a second region located on a side of the drain connection region away from the channel region; a width of the second sub-region of the source transition region is smaller than a width of the first region, or a width of the second sub-region of the drain transition region is smaller than a width of the second region.

14. The thin film transistor according to claim 1, wherein the source electrode is lapped on a first sub-region of the source transition region and is connected with the source connection region through a first via; the drain electrode is lapped on a first sub-region of the drain transition region and connected with the drain connection region through a second via.

15. The thin film transistor according to claim 14, wherein the shielding layer comprises a first shielding layer and a second shielding layer disposed at intervals, a boundary of an orthographic projection of the active layer on the base substrate is within a range of a boundary of an orthographic projection of the first shielding layer on the base substrate, and the source electrode is connected with the second shielding layer through a third via.

16. The thin film transistor according to claim 1, wherein the second sub-region is formed by a first conductorization treatment and a second conductorization treatment, the first sub-region is formed by a first conductorization treatment, the third sub-region is formed by a second conductorization treatment, and the channel region is formed during a self-aligned second conductorization treatment.

17. A display substrate, comprising: the thin film transistor according to claim 1.

18. A display apparatus, comprising the display substrate according to claim 17.

19. A preparation method of a thin film transistor, comprising:
forming a shielding layer, a buffer layer and an active layer sequentially on a base substrate;
forming a gate insulating layer and a conductive layer sequentially on the active layer, by performing two conductorization treatments, forming, in the active layer, a channel region, a source transition region and a drain transition region that are located at two sides of the channel region, a source connection region located on a side of the source transition region away from the channel region, and a drain connection region located on a side of the drain transition region away from the channel region; the conductive layer comprises a gate electrode, a source electrode and a drain electrode; the source connection region is connected with the source electrode, and the drain connection region is connected with the drain electrode; the source transition region and the drain transition region each comprise: a first sub-region, a second sub-region and a third sub-region connected sequentially, the first sub-region is located on a side of the second sub-region away from the channel region, the third sub-region is located on a side of the second sub-region close to the channel region, a thickness of the first sub-region and a thickness of the third sub-region are both equal to a thickness of the channel region, a thickness of the second sub-region is k times the thickness of the channel region, k is 0.8 to 1.5.

20. The preparation method according to claim 19, wherein the forming the shielding layer, the buffer layer and the active layer sequentially on the base substrate comprises:
forming the shielding layer and the buffer layer sequentially on the base substrate;
forming two layers of metal oxide films on the buffer layer, patterning the two layers of metal oxide films to form the active layer, the two layers of metal oxide films comprises a first metal oxide film and a second metal oxide film which are stacked, an oxygen element content of the second metal oxide film is larger than that of the first metal oxide film, and a power of the second metal oxide film is smaller than that of the first metal oxide film.
